(19) United States
(12) Patent Application Publication
(10) Pub. No.: US 2026/0324149 A1
(43) Pub. Date: Oct. 15, 2026

(54) ENCAPSULATION FILM ELEMENT, DISPLAY SUBSTRATE AND DISPLAY MODULE

(71) Applicants: BOE MLED Technology Co., Ltd., Beijing (CN); BOE Technology Group Co., Ltd., Beijing (CN); Beijing BOE Technology Development Co., Ltd., Beijing (CN)

(72) Inventors: Le ZHAO, Beijing (CN); Zezhou YANG, Beijing (CN); Shubai ZHANG, Beijing (CN); Wenjia SUN, Beijing (CN); Jiaxin LI, Beijing (CN); Liangliang JIN, Beijing (CN)

(21) Appl. No.: 18/994,129

(22) PCT Filed: Apr. 30, 2024
(86) PCT No.: PCT/CN2024/090866

§ 371 Date: Jan. 14, 2025

(30) Foreign Application Priority Data
Nov. 20, 2023 (CN) 202311552817.5

(51) Int. Cl. H10H 20/854; H10H 20/855; H10H 29/854; H10H 29/855

(52) U.S. Cl. CPC H10H 20/854; H10H 20/855; H10H 29/854; H10H 29/8552

(57) ABSTRACT

An encapsulation film element, a display substrate and a display module are provided. The encapsulation film element is used for encapsulating an LED display substrate, and includes a plastic film and an adhesive layer on one side of the plastic film; the plastic film includes a dark film, and a transmittance of the dark film to visible light is in a range from 30% to 60%.

### TECHNICAL FIELD

The present disclosure relates to the field of display technology, in particular to an encapsulation film element, a display substrate and a display module.

### BACKGROUND

A surface encapsulation method for a current LED (light emitting diode) direct-emitting product includes a film element encapsulation method. In the film element encapsulation method, an encapsulation film element for encapsulation includes a dark color layer, so that a surface of a display product is dark when the display product does not display.

### SUMMARY

The present disclosure provides an encapsulation film element, a display substrate and a display module.

In a first aspect, the present disclosure provides an encapsulation film element for encapsulating an LED display substrate, including a plastic film and an adhesive layer on one side of the plastic film; wherein the plastic film includes a dark film, and a transmittance of the dark film to visible light is in a range from 30% to 60%.

In some embodiments, the plastic film includes only the dark film, a material of the dark film is a base doped with black dye, and the base is any one of polyethylene terephthalate, polycarbonate, polyimide, and cellulose triacetate.

In some embodiments, the plastic film has a thickness greater than or equal to 50 micrometers.

In some embodiments, the plastic film includes a dark film and a transparent plastic layer, and the dark film is attached to the transparent plastic layer; and the dark film is made of black dye.

In some embodiments, the transparent plastic layer has a thickness greater than or equal to 50 micrometers.

In some embodiments, the adhesive layer includes diffusion particles for scattering light.

In some embodiments, the diffusion particles are made of at least one of silicon dioxide and titanium dioxide.

In some embodiments, the diffusion particles are uniformly distributed within the adhesive layer.

In some embodiments, the encapsulation film element includes a diffusion particle layer between the adhesive layer and the plastic film for scattering light.

In some embodiments, the encapsulation film element includes at least one of an anti-glare layer, an anti-reflection layer, and an anti-fouling layer on a surface of the plastic film away from the adhesive layer; and the anti-glare layer is a coating layer attached to a surface of the plastic film, or is obtained by treating the surface of the plastic film.

In some embodiments, the plastic film includes a first plastic layer and a second plastic layer which are stacked; one of the first plastic layer and the second plastic layer is a transparent film, and the other is the dark film; or the first plastic layer and the second plastic layer are both transparent films, the plastic film includes a first adhesive layer between the first plastic layer and the second plastic layer, and the first adhesive layer is the dark film.

In some embodiments, the first plastic layer is the transparent film and the second plastic layer is the dark film, or the first plastic layer is the dark film and the second plastic layer is the transparent film; and the plastic film includes a second adhesive layer between the first plastic layer and the second plastic layer, and a transmittance of the second adhesive layer to visible light is greater than that of the dark film to visible light.

In some embodiments, a transmittance of the transparent film to visible light is greater than 90%.

In some embodiments, the transmittance of the second adhesive layer to visible light is greater than or equal to 95%.

In some embodiments, the transparent film is made of any one of polyethylene terephthalate, polycarbonate, polyimide, and cellulose triacetate, and the dark film includes a base and carbon black particles dispersed in the base, wherein the base is made of any one of polyethylene terephthalate, polycarbonate, polyimide, and cellulose triacetate.

In some embodiments, a total thickness of the first plastic layer, the second plastic layer and the second adhesive layer in a range from 100 μm to 300 μm.

In some embodiments, the second adhesive layer is configured to scatter visible light.

In some embodiments, the first plastic layer and the second plastic layer are transparent films made of any one of polyethylene terephthalate, polycarbonate, polyimide, and cellulose triacetate; and the first adhesive layer includes an adhesive layer matrix and a black pigment in the matrix, and the adhesive layer matrix is made of a silicon-based optical adhesive or an epoxy resin.

In some embodiments, a transmittance of a combination of the first plastic layer, the second plastic layer, and the first adhesive layer to visible light is in a range from 30% to 60%.

In some embodiments, a total thickness of the first plastic layer, the second plastic layer and the first adhesive layer is in a range from 100 μm to 300 μm.

In some embodiments, a total thickness of the first plastic layer and the second plastic layer is in a range from 50 μm to 150 μm.

In some embodiments, the first adhesive layer is configured to scatter visible light.

In some embodiments, the encapsulation film element includes at least one of an anti-glare layer, an anti-reflection layer, and an anti-fouling layer on a surface of the second plastic layer away from the first plastic layer; and the anti-glare layer is a coating layer attached to a surface of the plastic film, or is obtained by treating the surface of the plastic film.

In some embodiments, the adhesive layer includes a matrix and scattering particles distributed within the matrix for scattering visible light.

In some embodiments, the adhesive layer further includes a black pigment within the matrix.

In some embodiments, the encapsulation film element further includes a first adhesive layer between the first plastic layer and the second plastic layer, wherein a hardness of a combination of the first plastic layer, the second plastic layer and the first adhesive layer is in a range from 2H to 4H; or the encapsulation film element further includes a second adhesive layer between the first plastic layer and the second plastic layer, and a hardness of a combination of the first plastic layer, the second plastic layer and the second adhesive layer is in a range from 2H to 4H.

The present disclosure further provides a display substrate, including a base substrate, LED light emitting chips, and the encapsulation film element of any one of claims 1 to 26, wherein the LED light emitting chips, and the encapsulation film element are on the base substrate; and wherein the LED light emitting chips are between the base substrate and the encapsulation film element.

In some embodiments, the adhesive layer includes first portions and second portions, each first portion is between the corresponding LED light emitting chip and the first plastic layer, and each second portion is between two adjacent LED light emitting chips, and the first portion and the second portion corresponding to each other are in contact with each other.

In some embodiments, the adhesive layer is conformal to a structure formed by assembling a surface of the base substrate close to the encapsulation film element and the LED light emitting chips.

In some embodiments, a surface of the plastic film close to the base substrate is parallel to the base substrate.

In some embodiments, the encapsulation film element includes a diffusion particle layer between the adhesive layer and the plastic film, and a surface of the diffusion particle layer close to the base substrate is parallel to the base substrate.

In some embodiments, the diffusion particle layer has a thickness greater than or equal to 26 micrometers.

In some embodiments, the plastic film has a thickness greater than or equal to 50 micrometers; and the adhesive layer has a thickness greater than or equal to 96 micrometers.

In some embodiments, the plastic film has a thickness greater than or equal to 50 micrometers with the diffusion particles uniformly distributed within the adhesive layer; and the adhesive layer has a thickness greater than or equal to 96 micrometers.

In some embodiments, a maximum distance H1 from a surface of the encapsulation film element away from the base substrate to the base substrate and a minimum horizontal distance D from the LED light emitting chip to an edge of the encapsulation film element satisfy: H1≤A×D, and A is between 1.12 and 1.31; and wherein the minimum horizontal distance is a minimum distance in a direction parallel to the base substrate.

In some embodiments, H1 is less than or equal to 230 micrometers.

The present disclosure further provides a display substrate, including a base substrate, LED light emitting chips and an encapsulation film element on the base substrate, wherein the LED light emitting chips are between the base substrate and the encapsulation film element; and the encapsulation film element includes an adhesive layer and a plastic film which are stacked, the adhesive layer is on a side of the plastic film close to the base substrate, the plastic film includes a transparent film, and a dark coating layer is attached to a surface of the base substrate close to the encapsulation film element.

In some embodiments, a maximum distance H1 from a surface of the encapsulation film element away from the base substrate to the base substrate and a minimum horizontal distance D from the LED light emitting chip to an edge of the encapsulation film element satisfy: H1≤A×D, and A is between 1.12 and 1.31; and wherein the minimum horizontal distance is a minimum distance in a direction parallel to the base substrate.

In some embodiments, the adhesive layer includes diffusion particles for scattering light.

In some embodiments, the present disclosure further provides a display module, including a plurality of the display substrates arranged in an array.

### BRIEF DESCRIPTION OF DRAWINGS

The accompanying drawings, which are provided for further understanding of embodiments of the present disclosure and constitute a part of this specification, are for explaining the present disclosure together with the embodiments of the present disclosure, but are not intended to limit the present disclosure. In the drawings:

FIG. 1 is a schematic diagram of an encapsulation film element according to some embodiments.

FIG. 2 is a schematic diagram of an encapsulation film element according to other embodiments.

FIGS. 3 to 10B are schematic diagrams illustrating various structures of an encapsulation film element according to an embodiment of the present disclosure.

FIGS. 11A to 11D are schematic diagrams illustrating various structures of a display substrate according to some embodiments of the present disclosure.

FIG. 11E is a schematic diagram of a display substrate according to other embodiments of the present disclosure.

FIG. 12 is a schematic diagram of a vacuum press-fit process according to an embodiment of the present disclosure.

FIG. 13 is a schematic diagram illustrating a normal display of a display substrate.

FIGS. 14 and 15 are schematic diagrams of a light path in which a color slit appear.

### DETAIL DESCRIPTION OF EMBODIMENTS

The embodiments of the present disclosure will be described in further detail below with reference to the accompanying drawings. It should be understood that the embodiments described here are only used to illustrate and explain the present disclosure, and not to limit the present disclosure.

To make the objects, technical solutions and advantages of the embodiments of the present disclosure more apparent, the technical solutions of the embodiments of the present disclosure will be clearly and completely described below with reference to the drawings of the embodiments of the present disclosure. Obviously, the described embodiments are only a few, not all of, embodiments of the present disclosure. All other embodiments, which can be derived by a person skilled in the art from the embodiments of the present disclosure without any creative effort, are within the protective scope of the present disclosure.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. The term of “comprising”, “including”, or the like, means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

As used herein, the term “parallel” or “perpendicular” includes the recited case and similar cases within an acceptable range of deviation as determined by one of ordinary skill in the art in view of a measurement in question and an error (i.e., a limitation of a measurement system) associated with a measurement of a particular quantity. For example, the term “parallel” includes absolute parallel and approximately parallel, and an acceptable range of deviation for the approximately parallel may be, for example, within 5°. The term “perpendicular” includes absolute perpendicular and approximately perpendicular, and for example, an acceptable range of deviation for the approximately perpendicular may be within 5°.

It will be understood that when a layer or an element is referred to as being “on” another layer or a substrate, the layer or the element may be directly on the other layer or the substrate, or intervening layers may be present therebetween.

Example embodiments are described herein with reference to cross-sectional views and/or plan views as idealized example drawings. In the drawings, a thickness of layers and a thickness of regions are exaggerated for clarity. Therefore, it can be expected that shapes in the drawings are changed as a result, for example, of manufacturing techniques and/or tolerances. Thus, the example embodiments should not be construed as limited to the shapes of regions illustrated herein but are to include deviations in the shapes as a result, for example, of manufacturing. Thus, the regions illustrated in the drawings are schematic in nature and their shapes are not intended to illustrate an actual shape of a region of a device and are not intended to limit the scope of the example embodiments.

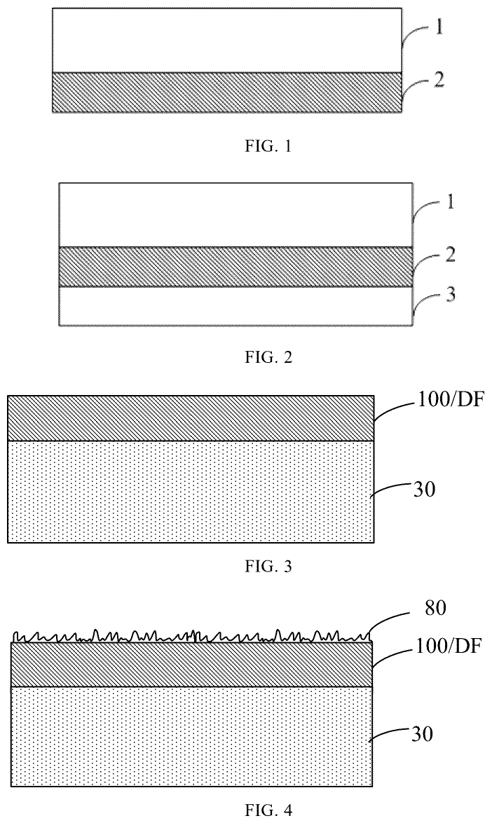

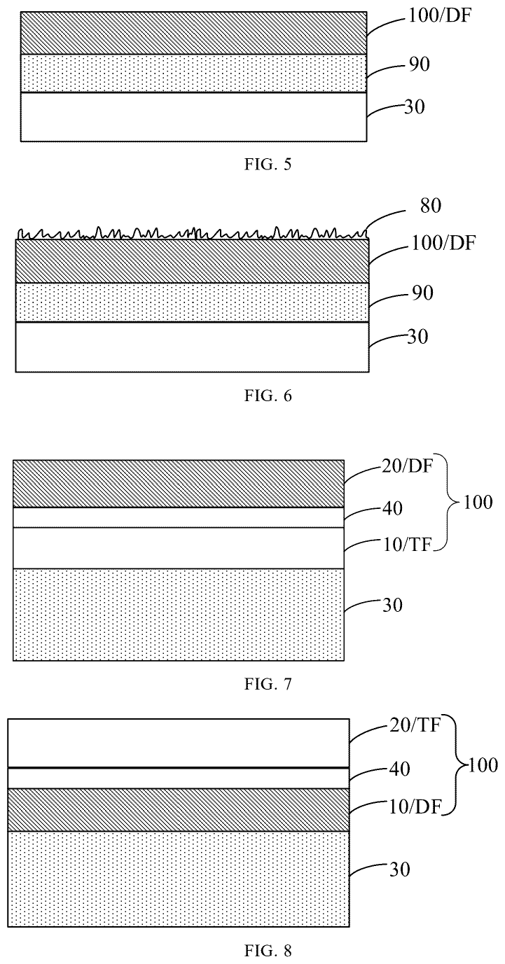

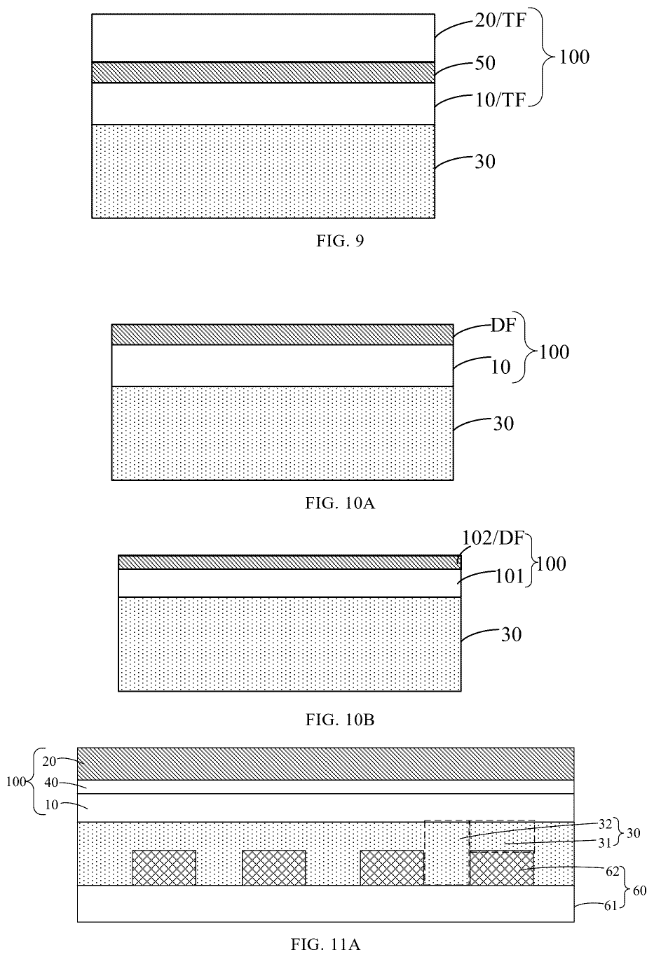

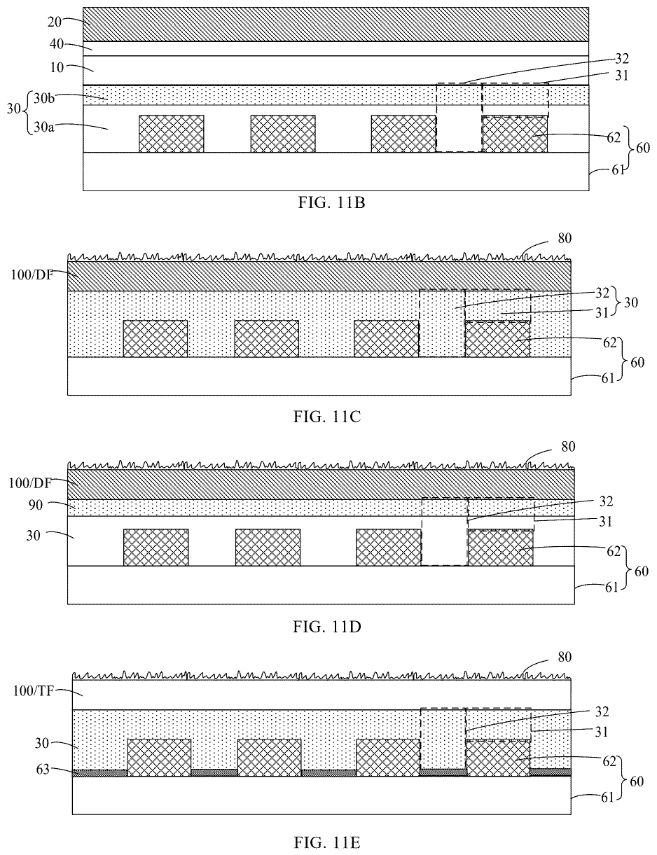

FIG. 1 is a schematic diagram of an encapsulation film element according to some embodiments. FIG. 2 is a schematic diagram of an encapsulation film element according to other embodiments. The encapsulation film element is used for encapsulating an LED display substrate. As shown in FIG. 1, the encapsulation film element includes: a transparent base 1 and a dark adhesive layer 2 provided on one side of the transparent base 1. In other embodiments, as shown in FIG. 2, the encapsulation film element includes: an adhesive layer 3, a dark adhesive layer 2, and the transparent base 1 sequentially stacked. When the LED display substrate is encapsulated by using the encapsulation film element of FIGS. 1 and 2, the encapsulation film element is press fit on the LED display substrate, so as to encapsulate the LED display substrate. After the encapsulation is completed, the dark adhesive layer 2 is located on a side of the transparent base 1 close to the display substrate. However, the dark adhesive layer 2 is usually formed by coating and curing a dark adhesive on the transparent base 1, and a thickness accuracy of the dark adhesive layer 2 is low due to the limitation of the coating process, so that an ink color of an encapsulation layer has a fluctuation (i.e., an L value of the encapsulation layer in the LAB space has a deviation from a target value). In addition, a hardness of the dark adhesive layer 2 formed with the cured adhesive is low, and after the encapsulation layer encapsulates the LED display substrate, a encapsulated chip is easy to extrude or pierce the dark adhesive layer 2, which also results in the low thickness accuracy of the dark adhesive layer 2. When a plurality of encapsulated display substrates are spliced into a spliced display screen with a large size, the ink colors at different positions of the spliced display screen are inconsistent.

In order to solve the above problems, the present disclosure provides an encapsulation film element for encapsulating an LED display substrate, where the LED display substrate may be a mini-LED display substrate or a micro-LED display substrate. FIGS. 3 to 10B are schematic diagrams illustrating various structures of an encapsulation film element according to an embodiment of the present disclosure. As shown in FIGS. 3 to 10B, the encapsulation film element includes a plastic film 100 and an adhesive layer 30 disposed on one side of the plastic film 100. The plastic film 100 includes a dark film DF, where the dark film DF in the embodiment of the present disclosure is a film that has a low transmittance (for example, not more than 75%) to visible light and is visually dark in color such as black, black gray, or the like.

In some embodiments, the transmittance of the dark film DF to visible light is in a range from 30% to 60%, for example, in a range from 30% to 40% or in a range from 40% and 60%.

In the embodiment of the present disclosure, the plastic film 100 is provided so that the encapsulation film element realizes the effect of visual ink color without the coating process. Compared with the adhesive layer formed with the cured adhesive, the hardness of the plastic film 100 is higher, and a thickness of the plastic film 100 cannot be affected by the extrusion of a light emitting chip, thereby reducing the ink color fluctuation of the encapsulation film element, and improving the ink color uniformity of the spliced display screen formed by splicing a plurality of encapsulated display apparatus.

The encapsulation film element in the present disclosure will be described in detail below with reference to the drawings.

In some embodiments, as shown in FIG. 3, the plastic film 100 includes only the dark film, a material of the dark film includes a base doped with a black dye, and a material of the base is any one of PET (polyethylene terephthalate), PC (polycarbonate), PI (polyimide), and TAC (cellulose triacetate).

In some embodiments, the thickness of the plastic film 100 is greater than or equal to 50 micrometers, to ensure that the encapsulation film element can provide a support with the sufficient mechanical strength.

For example, the thickness of the plastic film 100 is 50 micrometers, 60micrometers, 70 micrometers, 80 micrometers, or 90 micrometers.

In some embodiments, the adhesive layer 30 may include diffusion particles for diffusing light, so that the encapsulation film element may diffuse light from the LED display substrate to realize a uniform light outgoing effect.

For example, a material of the diffusion particles may include at least one of titanium dioxide, silicone, zirconium dioxide, and silicon dioxide. For example, the diffusion particles may include silicon dioxide particles, or titanium dioxide particles, or other particles such as silicone particles, or zirconium dioxide particles. Alternatively, the diffusion particles may include a mixture of at least two of the above particles.

In some embodiments, the diffusion particles are uniformly distributed in the adhesive layer 30 to improve the light outgoing uniformity of the light from the LED display substrate passing through the encapsulation film element.

In some embodiments, a matrix of the adhesive layer 30 is a transparent optical adhesive, such as a silicon-based optical adhesive or an epoxy.

In some embodiments, the matrix may be an ultraviolet (UV) cured product or a thermally cured product. Ultraviolet (UV) particles or thermally cured particles in the uncured matrix are cured after the matrix containing these particles is subjected to a curing process (an ultraviolet irradiation or a heat treatment), so that the matrix of the adhesive layer 30 as a whole can be hardened, and does not include any uncured portion, and a creep amount is reduced by about 50%, thereby greatly reducing the adhesion for disassembly and assembly. The curing treatment is a process of converting a substance (the matrix containing the ultraviolet particles or the thermally cured particles) from a low molecular weight to a high molecular weight (a substance produced after curing). By taking the ultraviolet curing as an example, the principle of the curing treatment may be: the ultraviolet particles have photosensitivity, and are photo-initiated under the irradiation of ultraviolet light to form excited molecules, the excited molecules are decomposed into free radicals or ions, and unsaturated organic matters undergo chemical reactions such as polymerization, grafting, crosslinking and the like, there realizing the curing.

In some embodiments, a thickness of the adhesive layer 30 may be greater than a height of an LED light emitting chip, so as to ensure that a portion of the adhesive layer 30 may be located on a side of the light emitting chip away from a base substrate after the encapsulation film element is attached to the display substrate, thereby protecting the LED light emitting chip, and preventing the LED light emitting chip from being damaged or preventing the plastic film 100 from being damaged by upward extrusion from components under the plastic film 100. In one example, a difference between the thickness of the adhesive layer 30 and the height of the LED light emitting chip is in a range from 10 μm to 100 μm, for example, in a range from 10 μm to 30 μm, or in a range from 20 μm to 50 μm, or in a range from 50 μm to 70 μm.

For example, the difference between the thickness of the adhesive layer 30 and the height of the LED light emitting chip is at least 16 micrometers. For example, the height of the LED light emitting chip is 80 micrometers, and therefore, the thickness of the adhesive layer 30 is greater than or equal to 96 micrometers.

In some embodiments, as shown in FIG. 4, the encapsulation film element includes the plastic film 100 and the adhesive layer 30, and the materials and thicknesses of the plastic film 100 and the adhesive layer 30 may be as described above for FIG. 3. In addition, in FIG. 4, the encapsulation film element may further include a surface treatment layer 80 on a side of the plastic film 100 away from the adhesive layer 30. The surface treatment layer 80 may include at least one of an anti-glare (AG) layer (not shown), an anti-reflection (AR) layer, and an anti-fouling (AF) layer (not shown). By providing the anti-glare layer, the encapsulation film element has the characteristic of anti-glare. By providing the anti-reflection layer, the encapsulation film element has the advantages of reducing reflection and improving display contrast. By providing the anti-fouling layer, the encapsulation film element has the characteristic of easy wiping. The anti-reflection layer may be formed by coating, and the anti-fouling layer may be formed by coating the plastic film 100.

The anti-glare layer may be obtained by treating (e.g., embossing) a surface of the plastic film 100. The treated surface of the plastic film 100 is formed as a rough surface having an anti-glare effect. In practical applications, only the surface of the plastic film 100 may be treated to form an anti-glare surface without providing the anti-reflection layer or the anti-fouling layer. At least one of the anti-reflection layer and the anti-fouling layer may be formed on a side of the anti-glare surface away from the adhesive layer 30 while the anti-glare surface is formed. At least one of the anti-reflection layer and the anti-fouling layer may be provided alone without providing the anti-glare surface.

It should be noted that in the above description, the surface of the plastic film 100 away from the adhesive layer 30 is treated to achieve the anti-glare effect of the encapsulation layer. In other examples, the anti-glare layer may also be attached to the surface of the plastic film 100. For example, a particle coating layer is additionally disposed on a side of the plastic film 100 away from the adhesive layer 30 to form the anti-glare layer, which can also achieve the anti-glare effect of the encapsulation film element.

In addition, when the anti-glare layer, the anti-reflection layer, and the anti-fouling layer are simultaneously disposed on the side of the plastic film 100 away from the adhesive layer 30, the anti-fouling layer is located on a side of the anti-reflection layer away from the plastic film 100, and the anti-glare layer is located on a side of the anti-reflection layer close to the plastic film 100.

It should be noted that when the anti-glare layer is a coating layer attached to the plastic film 100, a thickness of the plastic film 100 refers to a thickness of the plastic film 100 itself, and does not include a thickness of the anti-glare layer. If the anti-glare layer is obtained by surface-treating the plastic film 100, the thickness of the plastic film 100 is the thickness of the surface-treated plastic film 100.

In some embodiments, as shown in FIGS. 5 and 6, the encapsulation film element may include the above plastic film 100 and the adhesive layer 30, wherein the plastic film 100 includes a dark film DF, and a material of the dark film DF and a thickness of the plastic film 100 may refer to the above description for FIG. 3.

In some embodiments, as shown in FIGS. 5 and 6, the encapsulation film element may further include a diffusion particle layer 90 between the adhesive layer 30 and the plastic film 100 for scattering light. The diffusion particle layer 90 may include a cured transparent adhesive and diffusion particles uniformly distributed in the transparent adhesive. The diffusion particles may include silicon dioxide particles, titanium dioxide particles, other particles such as silicone particles, zirconium dioxide particles. Alternatively, the diffusion particles may include a mixture of at least two of the above particles.

By providing the diffusion particle layer 90, the encapsulation film element may scatter the light from the LED display substrate, thereby realizing a uniform light outgoing effect. Furthermore, before the encapsulation film element is attached to the display substrate, the diffusion particle layer 90 is completely cured, so that the anti-collision characteristic of the display product can be improved, and the diffusion particles can be prevented from not being uniformly distributed due to extrusion of the diffusion particle layer 90 when attaching the encapsulation film element.

In some embodiments, as shown in FIG. 5 and FIG. 6, the thickness of the adhesive layer 30 may be greater than the height of an LED light emitting chip, so as to ensure that a portion of the adhesive layer 30 may be located on a side of the light emitting chip away from the base substrate after the encapsulation film element is attached to the display substrate, thereby protecting the LED light emitting chip, and preventing the LED light emitting chip from being damaged or preventing the diffusion particle layer 90 from being damaged by upward extrusion from components under the diffusion particle layer 90. In one example, a difference between the thickness of the adhesive layer 30 and the height of the LED light emitting chip is in a range from 10 μm to 100 μm, for example, in a range from 10 μm to 30 μm, or in a range from 20 μm to 50 μm, or in a range from 50 μm to 70 μm.

For example, the difference between the thickness of the adhesive layer 30 and the height of the LED light emitting chip is at least 16 micrometers. For example, the height of the LED light emitting chip is 80 micrometers, the thickness of the adhesive layer 30 is greater than or equal to 96 micrometers.

In some embodiments, as shown in FIG. 6, except for the diffusion particle layer 90, the encapsulation film element may further include the surface treatment layer 80, so that the encapsulation film element may include at least one of anti-fouling, reflection reduction and anti-glare effects.

In the embodiment shown in FIGS. 7 to 9, the encapsulation film element includes the plastic film 100 and the adhesive layer 30 located on one side of the plastic film 100, wherein the plastic film 100 includes a first plastic layer 10 and a second plastic layer 20 which are stacked. For example, the adhesive layer is located on a side of the first plastic layer 10 away from the second plastic layer 20.

In some embodiments, as shown in FIGS. 7 and 8, one of the first plastic layer 10 and the second plastic layer 20 is a transparent film TF and the other is a dark film DF. The dark film DF and the transparent film TF are plastic layers without the coating process. Compared with the adhesive layer formed with the cured adhesive, the hardness of the plastic layer is higher, and a thickness of the plastic film 100 cannot be affected by the extrusion of a light emitting chip, thereby reducing the ink color fluctuation of the encapsulation film element, and improving the ink color uniformity of the spliced display screen formed by splicing a plurality of encapsulated display apparatus.

In another embodiment, as shown in FIG. 9, the first plastic layer 10 and the second plastic layer 20 are both transparent films TF, and the encapsulation film element includes a first adhesive layer 50 arranged between the first plastic layer 10 and the second plastic layer 20. A transmittance of the first adhesive layer 50 to visible light is less than that of each of the first plastic layer 10 and the second plastic layer 20 to visible light, so that the whole encapsulation film element is dark in color. The plastic layers are arranged on upper and lower sides of the first adhesive layer 50, and protect the first adhesive layer 50 due to the higher hardness of the plastic layer, which prevents a thickness accuracy of the first adhesive layer 50 from being affected by the extrusion of a light emitting chip, thereby reducing the ink color fluctuation of the encapsulation film element, and improving the ink color uniformity of the spliced display screen formed by splicing a plurality of encapsulated display apparatus.

In some embodiments, as shown in FIG. 7, the first plastic layer 10 is a transparent film TF and the second plastic layer 20 is a dark film DF. The encapsulation film element includes a second adhesive layer 40 arranged between the first plastic layer 10 and the second plastic layer 20, and a transmittance of the second adhesive layer 40 to visible light is greater than that of the dark film DF. When the LED display substrate is encapsulated by the encapsulation film element shown in FIG. 7, the dark film DF is farther away from the LED display substrate than the transparent film TF and the second adhesive layer 40, so that the visual ink color of the encapsulated display product is darker.

In an exemplary embodiment, in FIG. 7, the transmittance of the transparent film TF to visible light is greater than 90%, and the transmittance of the dark film DF to visible light is in a range from 20% to 75%, so that the display of the display product is not affected by the encapsulation film element, and the visual ink color effect is achieved when the display product does not display a picture. For example, the transmittance of the transparent film TF to visible light is in a range from 92% to 95%, or in a range from 95% to 98%, or above 98%, and the transmittance of the dark film DF to visible light is in a range from 30% to 60%, so that the normal display of the display product is guaranteed, and the good visual ink color effect is achieved. For example, the transmittance of the dark film DF to visible light is in a range from 30% to 40%, or in a range from 40% to 50%, or in a range from 50% to 60%.

For example, in FIG. 7, the transmittance of the second adhesive layer 40 to visible light is more than or 95%, to prevent the second adhesive layer 40 from affecting the display of the display product.

For example, in FIG. 7, a material of the transparent film TF is any one of PET (polyethylene terephthalate), PC (polycarbonate), PI (polyimide), and TAC (cellulose triacetate). The dark film DF includes a base and carbon black particles dispersed in the base, wherein the base is any one of PET, PC, PI and TAC. When the transparent film TF and the dark film DF are selected from the above materials, the transparent film TF and the dark film DF may have sufficient hardness to provide sufficient mechanical strength support (the support having a sufficient mechanical strength) for the whole encapsulation film element, and the problem of unstable ink color due to the extrusion of the encapsulation film element by the LED light emitting chip is avoided.

In FIG. 7, a total thickness of the first plastic layer 10, the second plastic layer 20 and the second adhesive layer 40 between the first plastic layer 10 and the second plastic layer 20 is greater than or equal to 100 micrometers, so as to enhance the support effect of the encapsulation film element. For example, the total thickness of the first plastic layer 10, the second plastic layer 20 and the second adhesive layer 40 between the first plastic layer 10 and the second plastic layer 20 is in a range from 100 μm to 300 μm, thereby improving the support effect of the encapsulation film element and preventing the thickness of the encapsulation film element from being much greater. For example, the total thickness is in a range from 100 μm to 150 μm, or in a range from 150 μm to 200 μm, or in a range from 200 μm to 300 μm.

A material of the second adhesive layer 40 is relatively soft, and the first plastic layer 10 and the second plastic layer 20 mainly have the support effect. Therefore, in order to further ensure the support effect of the encapsulation film element, in some embodiments, a total thickness of the first plastic layer 10 and the second plastic layer 20 is set to be greater than or equal to 50 micrometers. For example, the total thickness of the first plastic layer 10 and the second plastic layer 20 is in a range from 50 μm to 150 μm, such as in a range from 50 μm to 100 μm, or in a range from 100 μm to 150 μm.

For example, in FIG. 7, a hardness of a structure consisting of the first plastic layer 10, the second plastic layer 20 and the second adhesive layer 40 between the first plastic layer 10 and the second plastic layer 20 is in a range from 2H to 4H, so that the whole encapsulation film element is provided with sufficient mechanical strength support.

It should be noted that in FIGS. 7 to 9, the first plastic layer 10 and the second plastic layer 20 are used to support the encapsulation film element. In another example, only the dark film DF having a large thickness may be provided, and the transparent film TF and the second adhesive layer 40 may not be provided. In contrast, the transparent film TF, the dark film DF and the second adhesive layer 40 are provided at the same time, which has an advantage: a thickness of each of these three layers may be small, thereby facilitating the control of the thickness uniformity of the layers.

In some embodiments, the second adhesive layer 40 may be configured to scatter visible light, so that the encapsulation film element may diffuse light from the LED display substrate to realize the uniform light outgoing effect. For example, the second adhesive layer 40 may be doped with diffusion particles for scattering visible light, including, but not limited to, titanium dioxide particles, zirconium dioxide particles, silicon-based particles, silicon dioxide particles.

In some embodiments, at least one of the anti-glare (AG) layer (not shown), the anti-reflection (AR) layer, and the anti-fouling (AF) layer (not shown) is provided on a side of the second plastic layer 20 away from the first plastic layer 10, so that the encapsulation film element has the advantages of anti-glare, reflection reduction, easy wiping, etc. When forming the anti-glare layer, for example, the anti-glare surface may be formed by embossing a microstructure on the second plastic layer 20. Alternatively, the anti-glare layer is formed on a side of the second plastic layer 20 away from the first plastic layer 10, so that the encapsulation layer has anti-glare characteristics.

The anti-reflection layer may be formed by coating, and the anti-fouling layer may be formed by coating the second plastic layer 20.

In practical applications, one or more of the anti-glare layer, the anti-reflection layer, and the anti-fouling layer may be disposed on the second plastic layer 20, so that the encapsulation layer may achieve one or more of anti-glare, reflection reduction, and anti-fouling effects. When the anti-glare effect is realized, the anti-glare layer may be provided, or a surface of the second plastic layer 20 may be treated to form the anti-glare surface.

It should be noted that when the anti-glare layer is a coating layer attached to the second plastic layer 20, a thickness of the second plastic layer 20 refers to a thickness of the second plastic layer 20 itself, and does not include a thickness of the anti-glare layer. If the anti-glare layer is obtained by surface-treating the second plastic layer 20, the thickness of the second plastic layer 20 is the thickness of the surface-treated second plastic layer 20.

In some embodiments, the adhesive layer 30 in FIG. 7 may include a matrix and scattering particles distributed in the matrix, where the scattering particles are used to scatter visible light, so that the encapsulation film element may diffuse light from the LED display substrate to realize the uniform light outgoing effect. The scattering particles include, but are not limited to, titanium dioxide particles, zirconium dioxide particles, or silicon-based particles or the like. A particle diameter of each of these particles may be equal or greater than 4 μm and equal or less than 6 μm. For example, the particle diameter is 5 μm.

The matrix of the adhesive layer 30 is a transparent optical adhesive, such as a silicon-based optical adhesive or an epoxy resin.

For example, the adhesive layer 30 may further include a black pigment in the matrix, to adjust the transmittance and ink color of the whole encapsulation film element. The black pigment may be carbon black particles.

In some embodiments, the matrix may be an ultraviolet (UV) cured product or a thermally cured product. Ultraviolet (UV) particles or thermally cured particles in the uncured matrix are cured after the matrix containing these particles is subjected to a curing process (an ultraviolet irradiation or a heat treatment), so that the matrix of the adhesive layer 30 as a whole can be hardened, and does not include any uncured portion, and a creep amount is reduced by about 50%, thereby greatly reducing the adhesion for disassembly and assembly. The curing treatment is a process of converting a substance (the matrix containing the ultraviolet particles or the thermally cured particles) from a low molecular weight to a high molecular weight (a substance produced after curing). By taking the ultraviolet curing as an example, the principle of the curing treatment may be: the ultraviolet particles have photosensitivity, and are photo-initiated under the irradiation of ultraviolet light to form excited molecules, the excited molecules are decomposed into free radicals or ions, and unsaturated organic matters undergo chemical reactions such as polymerization, grafting, crosslinking and the like, there realizing the curing.

In some examples, the adhesive layer 30 in FIG. 7 may be a single layer structure including a matrix and scattering particles and/or black pigments in the matrix. In other examples, the adhesive layer 30 in FIG. 7 may be a composite layer, for example, the adhesive layer 30 includes a diffusion layer and a transparent adhesive layer which are stacked, the transparent adhesive layer is located on a side of the diffusion layer away from the first plastic layer 10, and the diffusion layer includes the above matrix and the scattering particles and/or the black pigments located in the matrix. A thickness of the adhesive layer 30 may be determined according to the height of the LED light emitting chip, wherein the LED light emitting chip is disposed on the base substrate, and the height of the LED light emitting chip is a vertical distance from a surface of the LED light emitting chip away from the base substrate to the base substrate. For example, the thickness of the adhesive layer 30 is greater than or equal to the height of the LED light emitting chip, so as to ensure that a portion of the adhesive layer 30 may be located on a side of the LED light emitting chip away from the base substrate after the adhesive layer 30 is press fit with the base substrate provided with the LED light emitting chip and the adhesive layer 30 is cured. Before the press-fit, the thickness of the adhesive layer 30 is greater than the height of the LED light emitting chip, so as to ensure that the portion of the adhesive layer 30 on a side of the LED light emitting chip away from the base substrate has a thickness of at least 5 micrometers after the press-fit. For example, a difference between the thickness of the adhesive layer 30 and the height of the LED light emitting chip is in a range from 0 to 50 μm, so as to ensure that the thickness of the portion of the adhesive layer 30 on the side of the LED light emitting chip away from the base substrate is in a range from 10 μm to 100 μm after the press-fit.

In one example, the height of the LED light emitting chip is in a range from 80 μm to 120 μm, and the thickness of the adhesive layer 30 is in a range from 80 μm to 170 μm.

In other embodiments, as shown in FIG. 8, the first plastic layer 10 is a dark film DF and the second plastic layer 20 is a transparent film TF. The encapsulation film element includes the second adhesive layer 40 arranged between the first plastic layer 10 and the second plastic layer 20, and a transmittance of the second adhesive layer 40 to visible light is greater than that of the dark film DF.

When the LED display substrate is encapsulated by using the encapsulation film element shown in FIG. 8, the transparent film TF is located on the upper layer, and reflects ambient light more uniformly, so that after a plurality of encapsulated LED display substrates are spliced into a large-sized spliced display screen, there is a small energy difference for the reflected light and heat dissipation light between a spliced gap and a display region of an LED display panel, and the overall display effect of the spliced display screen can be improved.

Similar to FIG. 7, in FIG. 8, the transmittance of the transparent film TF to visible light is greater than 90%, and the transmittance of the dark film DF to visible light is between 20% and 75%, so that the display of the display product is not affected by the encapsulation film element, and a visual ink color effect is achieved when the display product does not display a picture. For example, the transmittance of the transparent film TF to visible light is between 92% and 95%, or between 95% and 98%, or above 98%, and the transmittance of the dark film DF to visible light is between 30% and 60%, so that the normal display of the display product is guaranteed, and the good visual ink color effect is achieved. For example, the transmittance of the dark film DF to visible light is between 30% and 40%, or between 40% and 50%, or between 50% and 60%.

For example, in FIG. 8, the transmittance of the second adhesive layer 40 to visible light is greater than or equal to 95%, to prevent the second adhesive layer 40 from affecting the display of the display product.

For example, in FIG. 8, the material of the transparent film TF is any one of PET, PC, PI, and TAC. The dark film DF includes the base and carbon black particles dispersed in the base, wherein the base is any one of PET, PC, PI and TAC. When the transparent film TF and the dark film DF are selected from the above materials, the transparent film TF and the dark film DF can have sufficient hardness to provide sufficient mechanical strength support for the whole encapsulation film element, and the problem of unstable ink color due to the extrusion of the encapsulation film element by the LED light emitting chip is avoided.

As in FIG. 7, in FIG. 8, a total thickness of the first plastic layer 10, the second plastic layer 20 and the second adhesive layer 40 between the first plastic layer 10 and the second plastic layer 20 is greater than or equal to 100 micrometers, so as to enhance the support effect of the encapsulation film element. For example, the total thickness of the first plastic layer 10, the second plastic layer 20 and the second adhesive layer 40 between the first plastic layer 10 and the second plastic layer 20 is in a range from 100 μm to 300 μm, thereby improving the support effect of the encapsulation film element and preventing the thickness of the encapsulation film element from being much greater. For example, the total thickness is in a range from 100 μm to 150 μm, or in a range from 150 μm to 200 μm, or in a range from 200 μm to 300 μm.

A total thickness of the first plastic layer 10 and the second plastic layer 20 may be set to be greater than or equal to 50 micrometers. For example, the total thickness of the first plastic layer 10 and the second plastic layer 20 is in a range from 50 μm to 150 μm, such as in a range from 50 μm to 100 μm, or in a range from 100 μm to 150 μm.

A hardness of a structure consisting of the first plastic layer 10, the second plastic layer 20 and the second adhesive layer 40 between the first plastic layer 10 and the second plastic layer 20 is in a range from 2H to 4H, so that the whole encapsulation film element is provided with sufficient mechanical strength support.

In FIG. 8, at least one of the anti-glare layer, the anti-reflection layer, and the anti-fouling layer described above may also be provided on a side of the second plastic layer 20 away from the first plastic layer 10. In addition, the second adhesive layer 40 is configured to scatter visible light. For example, the second adhesive layer 40 may be doped with scattering particles. In FIG. 8, the specific structure and material of the adhesive layer 30 may refer to the above description for FIG. 7, and are not repeated here.

In still other embodiments, as shown in FIG. 9, the first plastic layer 10 and the second plastic layer 20 are both transparent films TF, and a first adhesive layer 50 is disposed between the first plastic layer 10 and the second plastic layer 20. The material of the transparent film TF is any one of PET, PC, PI, and TAC, so as to ensure that the transparent film TF has sufficient hardness, thereby providing sufficient mechanical support strength for the encapsulation film element.

The first adhesive layer 50 includes an adhesive layer matrix and a black pigment located in the matrix, and a material of the adhesive layer matrix may be a transparent optical adhesive, for example, a silicon-based optical adhesive or an epoxy resin. In practical applications, the transmittance and the ink color of the second adhesive layer 40 may be adjusted by adjusting the amount of the incorporated black pigments, thereby adjusting the transmittance and the ink color of the entire encapsulation film element.

For example, in the encapsulation film element shown in FIG. 9, the first adhesive layer 50 may be configured to scatter visible light, for example, the first adhesive layer 50 may further include scattering particles for scattering visible light, so that the encapsulation film element may scatter light from the LED display substrate to realize the uniform light outgoing effect.

For example, a transmittance of a combination of the first plastic layer 10, the second plastic layer 20 and the first adhesive layer 50 to visible light is in a range from 30% to 60%, so that the display of the display product is not affected by the encapsulation film element, and a visual ink color effect is achieved when the display product does not display a picture.

In the encapsulation film element shown in FIG. 9, the transmittance of each of the first plastic layer 10 and the second plastic layer 20 to visible light is greater than 90%, such as greater than 92%, or greater than 95%, or greater than 97%. The transmittance of the first adhesive layer 50 to visible light is in a range from 20% to 75%. Optionally, the transmittance of the first adhesive layer 50 to visible light is in a range from 30% to 60%, so that the normal display of the display product is ensured, and the good visual ink color effect is achieved. For example, the transmittance of the first adhesive layer 50 to visible light is in a range from 30% to 40%, or in a range from 40% to 50%, or in a range from 50% to 60%.

Similar to FIG. 7, in the encapsulation film element shown in FIG. 9, a total thickness of the first plastic layer 10, the second plastic layer 20 and the first adhesive layer 50 between the first plastic layer 10 and the second plastic layer 20 is greater than or equal to 100 micrometers, so as to enhance the support effect of the encapsulation film element. For example, a total thickness of the first plastic layer 10, the second plastic layer 20 and the second adhesive layer 40 between the first plastic layer 10 and the second plastic layer 20 is in a range from 100 μm to 300 μm, thereby improving the support effect of the encapsulation film element and preventing the thickness of the encapsulation film element from being much greater. For example, the total thickness of the first plastic layer 10, the second plastic layer 20 and the second adhesive layer 40 is in a range from 100 μm to 150 μm, or in a range from 150 μm to 200 μm, or in a range from 200 μm to 300 μm. Similar to FIG. 7, in FIG. 9, a total thickness of the first plastic layer 10 and the second plastic layer 20 is set to be greater than or equal to 50 micrometers. For example, the total thickness of the first plastic layer 10 and the second plastic layer 20 is in a range from 50 μm to 150 μm.

For example, a hardness of a structure consisting of the first plastic layer 10, the second plastic layer 20 and the first adhesive layer 50 between the first plastic layer 10 and the second plastic layer 20 is in a range from 2H to 4H, so that the whole encapsulation film element is provided with sufficient mechanical strength support.

In the encapsulation film element shown in FIG. 9, at least one of the anti-glare layer, the anti-reflection layer and the anti-fouling layer may also be disposed on a surface of the second plastic layer 20 away from the first plastic layer 10, as described above. In addition, in FIG. 9, the specific structure and material of the adhesive layer 30 may refer to the description for FIG. 7, and are not repeated here.

FIG. 10A is a schematic diagram of an encapsulation film element according to other embodiments of the present disclosure. As shown in FIG. 10A, the encapsulation film element includes an adhesive layer 30, and a plastic film 100 which are stacked, and the plastic film 100 includes a first plastic layer 10 and a dark film DF, wherein the dark film DF may be attached to a surface of the first plastic layer 10 close to the adhesive layer 30 or away from the adhesive layer 30. In FIG. 10A, only the dark film DF is attached to the surface of the first plastic layer 10 away from the adhesive layer 30.

In one example, the first plastic layer 10 is a transparent plastic layer, and the transmittance of the first plastic layer 10 is as described above for the transparent film TF. The material of the dark film DF may be a black dye. For example, the dark film may be an ink coating layer and may have a thickness less than or equal to 10 μm, such as a thickness between 3 μm and 5 μm.

In one example, a transmittance of a combination of the dark film DF and the first plastic layer 10 to visible light is in a range from 30% to 60% and a total thickness of the dark film DF and the first plastic layer 10 is in a range from 50 μm to 150 μm.

In one example, a thickness of the first plastic layer 10 is greater than or equal to 50 micrometers to ensure that the encapsulation film element can provide sufficient mechanical strength support. For example, the first plastic layer 10 has a thickness of 50 micrometers, or 60 micrometers, or 70 micrometers, or 80 micrometers, or 90 micrometers.

In one example, the hardness of the combination of the first plastic layer 10 and the dark film DF is between 2H and 4H, so that the whole encapsulation film element is provided with sufficient mechanical strength support.

In FIG. 10A, at least one of the anti-glare layer, the anti-reflection layer, and the anti-fouling layer may be provided with a side of the combination of the first plastic layer 10 and the dark film DF away from the adhesive layer 30. The specific structure and material of the adhesive layer 30 may refer to the above description for FIG. 7, and are not repeated here.

FIG. 10B is a schematic diagram of an encapsulation film element according to other embodiments of the present disclosure. As shown in FIG. 10B, the encapsulation film element includes an adhesive layer 30 and a plastic film 100 which are stacked, where the plastic layer 100 includes a first sub-layer 101 and a second sub-layer 102, where the first sub-layer 101 is a transparent plastic layer, and the second sub-layer 102 is a dyed layer as the dark film DF. In one example, the second sub-layer 102 and the first sub-layer 101 have a one-piece structure, and the second sub-layer 102 is formed by dyeing the transparent plastic layer, that is, the second sub-layer 102 includes a transparent plastic base and dyed particles in the transparent plastic base, and the dyed particles include carbon black particles.

It should be noted that in FIG. 10B, the second sub-layer 102 is illustrated as being located on a side of the first sub-layer 101 away from the adhesive layer 30. Alternatively, the second sub-layer 102 may be located on a side of the first sub-layer 101 close to the adhesive layer 30.

A transmittance of the first sub-layer 101 in the plastic film 100 to visible light may be greater than 90%, and a transmittance of the second sub-layer 102 to visible light may be in a range from 20% to 75%, for example, in a range from 30% to 60%. A material of the first sub-layer 101 may be any one of PET, PC, PI, TAC, and the like.

In some examples, a total thickness of the first sub-layer 101 and the second sub-layer 102 is greater than or equal to 50 micrometers, which may provide an effective support effect for the encapsulation film element. For example, the total thickness of the first sub-layer 101 and the second sub-layer 102 is in a range from 50 μm to 150 μm.

In one example, in FIG. 10B, the overall stiffness of the plastic film 100 is in a range from 2H to 4H, so that the whole encapsulation film element is provided with sufficient mechanical strength support.

In FIG. 10B, at least one of the anti-glare layer, the anti-reflection layer, and the anti-fouling layer may be provided on a surface of the plastic film 100 away from the adhesive layer 30.

In FIG. 10B, the specific structure and material of the adhesive layer 30 may refer to the description for FIG. 7, and are not repeated here.

In the encapsulation film element provided by the embodiments, by controlling the material and the thickness of each layer, the transmittance of the whole encapsulation film element to visible light may be in a range from 20% to 75%, for example, in a range from 30% to 60%, and an L value of the whole encapsulation film element in the LAB space is smaller than 31.5, for example, in a range from 28 to 30.

FIGS. 11A to 11D are schematic diagrams illustrating various structures of a display substrate according to some embodiments of the present disclosure. As shown in FIGS. 11A to 11D, the display substrate includes a base substrate 61, LED light emitting chips 62 and an encapsulation film element disposed on the base substrate 61, the encapsulation film element is the encapsulation film element in any one of the embodiments, and the LED chips are located between the base substrate 61 and the encapsulation film element and on a side of the adhesive layer 30 away from the plastic film.

In some embodiments, the base substrate 61 may be a PCB board or a glass board.

In some embodiments, the LED light emitting chips 62 are mini-LED chips or micro-LED chips.

As shown in FIGS. 11A to 11D, the adhesive layer 30 includes first functional portions 31 and second functional portions 32, each first functional portion 31 is located between the corresponding LED light emitting chip 62 and the plastic film 100, each second functional portion 32 is located between two adjacent LED light emitting chips 62, and the first functional portion 31 and the second functional portion 32 corresponding to each other are in contact with each other. In this case, a thickness of each second functional portion 32 is greater than that of each LED light emitting chips 62, so that the first functional portion 31 and the second functional portion 32 corresponding to each other are in contact with each other, and thus the LED light emitting chips 62 may be completely covered by the first functional portions 31 and the second functional portions 32, thereby better preventing the LED light emitting chips 62 from being damaged by extrusion.

In some embodiments, the first functional portion 31 and the second functional portion 32 corresponding to each other are in contact with each other. On this basis, each second functional portion 32 is in contact with the base substrate 61 and the plastic film 100, respectively, and each first functional portion 31 is in contact with the corresponding LED light emitting chip 62 and the plastic film 100, respectively. In this case, the thickness of each second functional portion 32 is equal to or is substantially equal to a sum of the thicknesses of each first functional portion 31 and each light emitting chip 62. In this way, the first functional portions 31 and the second functional portions 32 may be completely filled between the first plastic film 10 and the base substrate 61, thereby better protecting the LED light emitting chips 62.

In some embodiments, the plurality of LED light emitting chips 62 are separated from each other by the second functional portions 32, and are in direct contact with the corresponding second functional portions 32, so that each second functional portion 32 can protect the corresponding LED light emitting chip 62 at the periphery of the corresponding LED light emitting chip 62, and the LED light emitting chip is prevented from being damaged by extrusion due to the contact with the first plastic film 10 after the LED light emitting chip 62 is encapsulated by the encapsulation film element.

In some embodiments, an orthographic projection of each first functional portion 31 on a plane where the first plastic film 10 is located covers a center of an orthographic projection of a light emitting region of the corresponding light emitting chip 62 on the plane where the first plastic film 10 is located. Each first functional portion 31 may partially cover the light emitting region of the corresponding LED light emitting chip 62, i.e., cover the center of the light emitting region, so that the light outgoing effect of the display substrate is better.

In some embodiments, the orthographic projection of each first functional portion 31 on the plane where the first plastic film 10 is located covers the orthographic projection of the light emitting region of the corresponding light emitting chip 62 on the plane where the first plastic film 10 is located. Each first functional portion 31 may completely cover the light emitting region of the corresponding LED light emitting chip 62 In some embodiments, as shown in FIGS. 11A and 11C, the adhesive layer 30 may be a single layer structure, and materials of the first functional portion 31 and the second functional portion 32 are the same, and may refer to the description for the adhesive layer 30.

In other embodiments, as shown in FIG. 11B, the adhesive layer 30 may alternatively be a composite layer formed by layers. For example, the adhesive layer 30 includes a transparent adhesive layer 30a and a diffusion layer 30b which are stacked, the diffusion layer 30b is located on a side of the transparent adhesive layer 30a away from the base substrate 61, and a transmittance of the transparent adhesive layer 30a to visible light may be greater than 90%. The diffusion layer 30 b includes the matrix layer and the scattering particles and/or black pigments in the matrix layer.

When the adhesive layer 30 is a composite layer, a portion of the diffusion layer 30b is located on a side of the corresponding LED light emitting chip 62 away from the base substrate 61, and a relationship between a thickness of the transparent adhesive layer 30a and the height of the LED light emitting chip 62 is not limited. That is, as shown in FIG. 11B, each second functional portion 32 includes a portion of the diffusion layer 30b and a portion of the transparent adhesive layer 30a, and each first functional portion 31 may include a portion of the diffusion layer 30b and a portion of the transparent adhesive layer 30a. Alternatively, each first functional portion 31 may include only a part of the diffusion layer 30b.

In still other embodiments, as shown in FIG. 11D, a diffusion particle layer 90 is further disposed between the adhesive layer 30 and the plastic film, the adhesive layer 30 includes first functional portions 31 and second functional portions 32, each first functional portion 31 is located between the corresponding LED light emitting chip 62 and the diffusion particle layer 90, each second functional portion 32 is located between two adjacent LED light emitting chips 62, and the first functional portion 31 and the second functional portion 32 corresponding to each other are in contact with each other. In this case, each of each first functional portion 31 and each second functional portion 32 includes a portion of the diffusion particle layer 90 and a portion of the adhesive layer 30. Alternatively, each first functional portion 31 may include only a part of the diffusion particle layer 90.

In some embodiments, as shown in FIGS. 11A to 11D, the adhesive layer 30 is conformal to a structure formed by assembling a surface of the base substrate 61 close to the encapsulation film element and the LED light emitting chips 62. In other words, the lamp panel 60 is regarded as the structure formed by assembling the base substrate 61 and the plurality of LED light emitting chips 62 on the base substrate 61, and a surface of the adhesive layer 30 close to the lamp panel 60 is conformal to a surface of the whole lamp panel 60 close to the encapsulation film element.

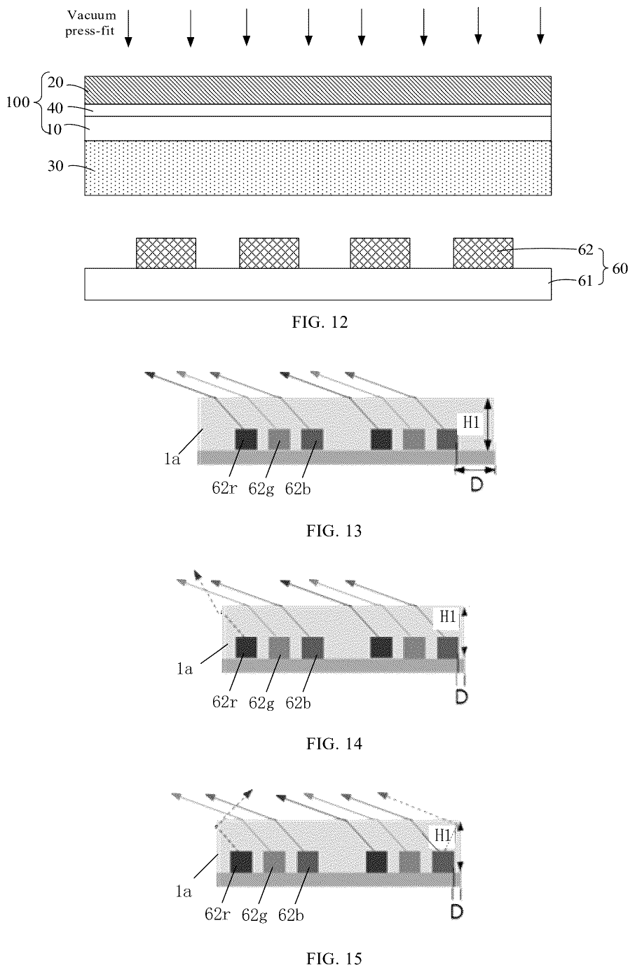

In this case, the adhesive layer 30 may be formed on the lamp panel 60 by a press-fit process. Specifically, a functional material (which is gelatineous and may deform) is formed on a surface of the plastic film 100. In the press-fit process, a whole cavity for the press-fit process is vacuumized, and then air is introduced into one side of the plastic film 100 in the cavity away from the base substrate, so that an air pressure difference exists between two opposite sides of the encapsulation film element, and the encapsulation film element may be press fit onto the lamp panel 60 through the air pressure difference. The vacuum press-fit process is shown in FIG. 12. The functional material on surfaces of the LED light emitting chips 62 away from the base substrate 61 is extruded and therefore overflows to between every two adjacent LED light emitting chips 62, so that a surface of the functional material layer close to the base substrate 61 is conformal to the surface of the whole lamp panel 60 close to the functional material layer. Thereafter, the functional material is cured, so as to form the adhesive layer 30 conformal to the surface of the lamp panel 60 close to the encapsulation film element. The remaining material on the surfaces of the LED light emitting chips 62 away from the base substrate 61 forms the first functional portions 31, and one second functional portion 32 is formed between every two adjacent LED light emitting chips 62.

In some embodiments, the thickness of the cured adhesive layer 30 is greater than the height of each LED light emitting chip 62, and a portion of the adhesive layer 30 may be located on a side of the LED light emitting chips away from the base substrate, so as to protect the LED light emitting chips. In one example, a difference between the thickness of the adhesive layer 30 and the height of the LED light emitting chip 62 is between 10 μm and 100 μm, for example, between 10 μm and 30 μm, or between 30 μm and 50 μm, or between 50 μm and 70 μm.

It is understood that when there is no other layer between the adhesive layer 30 and the plastic film 100, the difference between the thickness of the adhesive layer 30 and the height of the LED light emitting chip 62 is a thickness of each first functional portion 31.

In some embodiments, as shown in FIGS. 11A to 11D, a surface of the plastic film 100 close to the base substrate 61 is parallel to the base substrate 61, that is, the surface of the plastic film 100 close to the base substrate 61 is a flat surface, which does not fluctuate with the adhesive layer 30, so as to realize a stable support effect.

In some embodiments, as shown in FIG. 11D, in the case where the encapsulation film element includes the diffusion particle layer 90, a surface of the diffusion particle layer 90 close to the base substrate 61 is parallel to the base substrate. In practical applications, before the encapsulation film element is attached to the base substrate 61, the diffusion particle layer 90 is completely cured, so that the surface of the diffusion particle layer 90 close to the base substrate 91 is parallel to the base substrate 91, thereby improving the anti-collision characteristic of the product, and preventing the diffusion particles from not being uniformly distributed due to extrusion of the diffusion particle layer 90 by the LED light emitting chips 62 when attaching the encapsulation film element.

The inventors have found that when the encapsulation film element has a relatively great thickness, a color slit is liable to occur, and causes of the color slit will be described below.

FIG. 13 is a schematic diagram illustrating a normal display of a display substrate. As shown in FIG. 13, the LED light emitting chips 62 on the display substrate include a plurality of red chips 62r, a plurality of green chips 62g, and a plurality of blue chips 62b. The plurality of LED light emitting chips 62 constitute a plurality of light emitting chip groups, each of which includes a red chip 62r, a green chip 62g, and a blue chip 62b. When the display picture is observed by human eyes, the light emitted by the LED light emitting chips is emitted through a surface of the encapsulation film element 1a to the human eyes and is accepted by the user, so that the middle LED light emitting chip may be regarded as a normal display pixel. That is, an angle for the emitted light needs to be smaller than the total reflection angle of the encapsulation film element 1a , so that the emitted light may be emitted outward through the surface of the encapsulation film element 1a , and the light having the angle larger than the total reflection angle is transmitted inside the encapsulation film element 1a until the energy of the light is exhausted. If the LED light emitting chip at an edge is to be displayed normally, the emitted light having the angle smaller than the total reflection angle may be emitted outward through the surface of the encapsulation film element 1a, and cannot reach a side surface of the encapsulation film element 1a, that satisfies the theoretical formula, (D/H1)≥tan(arcsin(1/n)). D is a minimum horizontal distance from the LED light emitting chip 62 to an edge of the encapsulation film element 1a. The minimum horizontal distance refers to a minimum distance from the LED light emitting chip 62 to the edge of the encapsulation film element 1a in a direction parallel to the base substrate. D is less than or equal to a distance between any two adjacent light emitting chip groups. H1 is a maximum distance from a surface of the encapsulation film element 1a away from the base substrate 61 to the base substrate 61, and n is an average refractive index of the encapsulation film element.

FIGS. 14 and 15 are schematic diagrams of a light path in which a color slit appear. FIG. 14 is a schematic diagram of cyan slits, and FIG. 15 is a schematic diagram of blue slits. When H1 and D do not satisfy the above theoretical formula, that is, when the light to be emitted outward through an upper surface of the encapsulation film element 1a firstly reaches the side surface of the encapsulation film element 1a, the light path is abnormal. According to a state of the side surface of the encapsulation film element 1a, if the side surface is rough or blackened, light may be scattered or absorbed, so that an energy in an original normal emergent direction is reduced, and when observing in a direction of the red chip, red light is lacked to form the cyan slits. If the side surface is smooth, the light may be totally reflected by the side surface, so that the energy in the original normal emergent direction is reduced, the energy is enhanced in the opposite direction, and when observing in the direction of the red chip, the blue color is enhanced to form the blue slits.

It can be seen from an analysis for an optical path that in order to eliminate the color slits, with a fixed average refractive index n of the encapsulation film element, D and H1 must satisfy the theoretical formula, so as to ensure that the light is emitted outward through the upper surface, not the side surface, of the encapsulation film element. When D is small, H1 needs to be relatively small accordingly. A viewing angle of the observed color slit may be obtained by formula calculation, which is θ>arcsin(n×sin(arctan(D/H1))). If the color slit is not visible at all, i.e., the viewing angle is θ=90°, it satisfies H1≤1.12×D with n=1.5; it satisfies H1≤1.31D with n=1.65. For example, in a specific example, D=183.8 micrometers, n=1.5, H1≤205.5 micrometers, when the encapsulation film element adopts the structure in FIG. 3, for example, the thickness of the plastic film 100 is set to be 65 micrometers, and the thickness of the adhesive layer is set to be 125 micrometers, the requirement of no color slit can be satisfied.

H1≤1.12×D is only an example, and in practical applications, H1≤A×D. A is between 1.12 and 1.31, and n is between 1.5 and 1.65. When n=1.5, A is 1.12. When n=1.65, A=1.31.

It should be noted that when the encapsulation film element includes the adhesive layer 30 and the plastic layer 100, the refractive indexes of the plastic layer 100 and the adhesive layer 30 are approximately equal to each other. For example, the plastic film 100 is a PET substrate, the matrix of the adhesive layer 30 is acrylic resin, and the refractive indexes of the adhesive layer 30 and the plastic layer 100 are both about 1.5. For another example, the plastic film 100 is a PI substrate, the matrix of the adhesive layer 30 is epoxy resin, and the refractive indexes of the adhesive layer 30 and the plastic layer 100 are both about 1.65. Therefore, in actual calculation, n may be specifically considered to be approximately the refractive index of the matrix (excluding the diffusion particles) of the adhesive layer 30, which has little influence on the relationship between H1 and D.

In addition, it should be noted that the viewing angle refers to an angle between a viewing direction and a thickness direction of the encapsulation layer.

In some embodiments, the thickness of the plastic film 100 is greater than or equal to 50 micrometers to ensure the support effect of the encapsulation film element. Under the condition that the diffusion particles are uniformly distributed in the adhesive layer 30, the thickness of the adhesive layer 30 is greater than or equal to 96 micrometers, which ensures that portions of the adhesive layer 30 exist on a side of the LED light emitting chips 62 away from the base substrate 61, thereby preventing the plastic film 100 from being damaged or preventing the LED light emitting chips from being scratched by upward extrusion due to the LED light emitting chips 62 in contact with the plastic film 100.

As an example, the encapsulation film element adopts the structure in FIG. 4, the encapsulation film element includes the adhesive layer 30 and the plastic film 100, and the surface treatment layer 80 is disposed on a side of the plastic film 100 away from the adhesive layer 30. Assuming that the thickness of the surface treatment layer 80 is 10 micrometers, the total thickness of the plastic film 100 and the adhesive layer 30 needs to be less than or equal to 220. As above, the minimum value of the thickness of the adhesive layer 30 is 96. Considering that after the encapsulation film element is attached to the base substrate 61, the LED light emitting chips 62 are inserted into the adhesive layer 30, which increases the thickness of the adhesive layer 30 by 5 micrometers, and therefore the maximum thickness of the plastic film 100 is (220−96−5)=119 micrometers. In addition, the minimum thickness of the plastic film 100 is 50 micrometers to ensure the support effect, and thus, the maximum thickness of the adhesive layer 30 is (220−50−5)=165 micrometers. In summary, the thickness of the adhesive layer 30 is in a range from 96 micrometers to 165 micrometers, and the thickness of the plastic film 100 is in a range from 50 micrometers to 119 micrometers.

In some embodiments, in a case where the encapsulation film element includes the diffusion particle layer 90 between the adhesive layer 30 and the plastic film 100, the thickness of the diffusion particle layer 90 is greater than or equal to 26 micrometers. If the thickness of the diffusion particle layer 90 is too small, it is necessary to increase a concentration of the diffusion particles to ensure the diffusion effect, but which causes the unstable coating. The thickness of the diffusion particle layer 90 is set to be greater than or equal to 26 micrometers in the embodiment of the present disclosure, so that the coating stability can be improved, and the diffusion effect can be ensured.

As an example, the encapsulation film element adopts the structure in FIG. 6, the encapsulation film element includes the adhesive layer 30, the plastic film 100, and the diffusion particle layer 90 located between the adhesive layer 30 and the plastic film 100. The surface treatment layer 80 is disposed on a side of the plastic film 100 away from the adhesive layer 30. Assuming that the thickness of the surface treatment layer 80 is 10 micrometers, a total thickness of the plastic film 100, the adhesive layer 30 and the diffusion particle layer 90 needs to be less than or equal to 220 micrometers. As above, the minimum thickness of the plastic film 100 is 50 micrometers to ensure the support effect of the encapsulation film element. The minimum thickness of the adhesive layer 30 is 96 micrometers, thereby preventing the plastic film 100 from being damaged or preventing the LED light emitting chips from being scratched by upward extrusion due to the LED light emitting chips 62 in contact with the plastic film 100. In addition, considering that after the encapsulation film element is attached to the base substrate, the LED light emitting chips 62 are inserted into the adhesive layer 30, which increases the thickness of the adhesive layer 30 by 5 micrometers, and therefore the maximum thickness value of the diffusion particle layer 90 may be set to (220−96−5−50)=69 micrometers. When the minimum thickness of the diffusion particle layer 90 is 26 micrometers, and the minimum thickness value of the adhesive layer 30 is 96 micrometers, considering that the thickness of the attached adhesive layer 30 is increased by 5 micrometers, the maximum thickness value of the plastic layer may be set to (220−26−96−5)=93 micrometers. When the minimum thickness value of the plastic layer is 50 micrometers, and the minimum thickness value of the diffusion particle layer 90 is 26 micrometers, considering that the thickness of the attached adhesive layer 30 is increased by 5 micrometers, the maximum thickness of the adhesive layer 30 may be set to (220−50−26−5)=139 micrometers. In summary, the thickness of the adhesive layer 30 is in a range from 96 micrometers to 139 micrometers, the thickness of the diffusion particle layer 90 is in a range from 26 micrometers to 69 micrometers, and the thickness of the plastic layer is in a range from 50 to 93 micrometers.

FIG. 11E is a schematic diagram of a display substrate according to other embodiments of the present disclosure. As shown in FIG. 11E, the display substrate includes the base substrate 61, the LED light emitting chips 62 and the encapsulation film element located on the base substrate 61. In FIG. 11E, the encapsulation film element includes the adhesive layer 30 and the plastic film 100, and the plastic film 100 includes only the transparent film TF, wherein the transmittance of the transparent film TF to visible light is above 85%, for example, between 85% and 90%, or between 90% and 95%, or above 95%.

In some embodiments, the diffusion particles may be included in the adhesive layer 30 in FIG. 11E for scattering light, which specifically refers to the above description for FIG. 3, and is not described herein again.

In some embodiments, in FIG. 11E, the surface treatment layer 80 may be provided on a side of the plastic film 100 away from the base substrate 61, and may include one or more of the anti-glare layer, the anti-reflection layer, and the anti-fouling layer as described above. Alternatively, when the anti-glare effect is achieved, the surface of the plastic film 100 may be treated so that the surface of the plastic film 100 away from the adhesive layer 30 is formed as a rough surface with the anti-glare effect, which specifically refers to the above description for FIG. 4.

In FIG. 11E, a dark coating layer 63, e.g., an ink coating layer, is attached to a surface of the base substrate 61 close to the encapsulation film element. The dark coating layer 63 includes open regions where the corresponding LED light emitting chips 62 are located. In this case, the display substrate may achieve a high transmittance and a visual ink color effect when no image is displayed. A material of the dark coating layer 63 includes, for example, carbon black, or a black matrix material commonly used in a color filter substrate of a liquid crystal display panel.

In FIG. 11E, the thickness of the encapsulation film element may also be less than or equal to A×D, to avoid the color slit. As with the encapsulation film element in FIG. 4, in the encapsulation film element in FIG. 11E, the thickness of the adhesive layer 30 is greater than or equal to 96 micrometers, and the thickness of the plastic film 100 is greater than or equal to 50 micrometers. For example, the thickness of the adhesive layer 30 is in a range from 96 micrometers to 165 micrometers, and the thickness of the plastic film 100 is in a range from 50 micrometers to 119 micrometers.

The embodiment of the present disclosure further provides a display module, which includes a plurality of display substrates arranged in an array, and each display substrate adopts the display substrate in any one of the above embodiments.

It should be noted that in order to reduce a spliced gap in a display screen, the spliced gap “gap” between two adjacent display substrates should be as small as possible, where the minimum horizontal distance D and the spliced gap “gap” from the LED light emitting chip 62 to the edge of the encapsulation film element 1a may satisfy: a value of 2×D+gap is smaller than or equal to a distance between two adjacent light emitting chip groups on one display substrate in a direction of the minimum horizontal distance D from the LED light emitting chip 62 to the edge of the encapsulation film element 1a.

The embodiment of the present disclosure further provides an method for encapsulating a display substrate, wherein the display substrate includes a base substrate and an LED light emitting chip located on the base substrate. The method for encapsulating the display substrate includes steps S1 and S2.

The step S1 includes providing an encapsulation film element, wherein the encapsulation film element is the encapsulation film element in the above embodiments.

The step S2 includes pressing the encapsulation film element on the display substrate, wherein portions of the adhesive layer are located between the LED light emitting chips and the plastic film, and the other portions are located between two adjacent LED light emitting chips.

After the press-fit process and the curing, the portions of the adhesive layer between the LED light emitting chips and the plastic film are the first functional portions, and the portions of the adhesive layer between the two adjacent LED light emitting chips are the second functional portions. The press-fit process may be a vacuum press-fit process, which is specifically described above and will not be described herein again.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. An encapsulation film element for encapsulating an LED display substrate, comprising a plastic film and an adhesive layer on one side of the plastic film;
wherein the plastic film comprises a dark film, and a transmittance of the dark film to visible light is in a range from 30% to 60%.

2. The encapsulation film element of claim 1, wherein the plastic film comprises only the dark film;
a material of the dark film is a base doped with black dye; and
the base is any one of polyethylene terephthalate, polycarbonate, polyimide, and cellulose triacetate.

3. (canceled)

4. The encapsulation film element of claim 1, wherein the plastic film comprises the dark film and a transparent plastic layer, and the dark film is attached to the transparent plastic layer; and
the dark film is made of black dye.

5. (canceled)

6. The encapsulation film element of claim 1, wherein the adhesive layer comprises diffusion particles for scattering light.

7-8. (canceled)

9. The encapsulation film element of claim 1, wherein the encapsulation film element comprises a diffusion particle layer between the adhesive layer and the plastic film to scatter light.

10. The encapsulation film element of claim 1, wherein the encapsulation film element comprises at least one of an anti-glare layer, an anti-reflection layer, and an anti-fouling layer on a surface of the plastic film away from the adhesive layer; and
wherein the anti-glare layer is a coating layer attached to the surface of the plastic film, or is obtained by treating the surface of the plastic film.

11. The encapsulation film element of claim 1, wherein the plastic film comprises a first plastic layer and a second plastic layer which are stacked together;
one of the first plastic layer and the second plastic layer is a transparent film, and the other is the dark film; or
the first plastic layer and the second plastic layer each are a transparent film, the plastic film comprises a first adhesive layer between the first plastic layer and the second plastic layer, and the first adhesive layer is the dark film.

12. The encapsulation film element of claim 11, wherein the first plastic layer is the transparent film and the second plastic layer is the dark film, or the first plastic layer is the dark film and the second plastic layer is the transparent film; and
the plastic film comprises a second adhesive layer between the first plastic layer and the second plastic layer, and a transmittance of the second adhesive layer to visible light is greater than that of the dark film to visible light.

13. The encapsulation film element of claim 12, wherein a transmittance of the transparent film to visible light is greater than 90%.

14. The encapsulation film element of claim 13, wherein the transmittance of the second adhesive layer to visible light is greater than or equal to 95%.

15. The encapsulation film element of claim 12, wherein the transparent film is made of any one of polyethylene terephthalate, polycarbonate, polyimide, and cellulose triacetate, and the dark film comprises a base and carbon black particles dispersed in the base; and
wherein the base is made of any one of polyethylene terephthalate, polycarbonate, polyimide, and cellulose triacetate.

16. (canceled)

17. The encapsulation film element of claim 12, wherein the second adhesive layer is configured to scatter visible light.

18. The encapsulation film element of claim 11, wherein the first plastic layer and the second plastic layer each is a transparent film made of any one of polyethylene terephthalate, polycarbonate, polyimide, and cellulose triacetate; and
the first adhesive layer comprises an adhesive layer matrix and a black pigment in the matrix, and the adhesive layer matrix is made of a silicon-based optical adhesive or an epoxy resin.

19. The encapsulation film element of claim 18, wherein a transmittance of a combination of the first plastic layer, the second plastic layer, and the first adhesive layer to visible light is in a range from 30% to 60%.

20-21. (canceled)

22. The encapsulation film element of claim 11, wherein the first adhesive layer is configured to scatter visible light.

23. The encapsulation film element of claim 11, wherein the encapsulation film element comprises at least one of an anti-glare layer, an anti-reflection layer, and an anti-fouling layer on a surface of the second plastic layer away from the first plastic layer; and
wherein the anti-glare layer is a coating layer attached to the surface of the plastic film, or is obtained by treating the surface of the plastic film.

24. The encapsulation film element of claim 11, wherein the adhesive layer comprises a matrix and scattering particles distributed within the matrix for scattering visible light.

25. The encapsulation film element of claim 24, wherein the adhesive layer further comprises a black pigment within the matrix.

26. (canceled)

27. A display substrate, comprising a base substrate, LED light emitting chips, and the encapsulation film element of claim 1, wherein
the LED light emitting chips, and the encapsulation film element are on the base substrate; and
the LED light emitting chips are between the base substrate and the encapsulation film element;
wherein the adhesive layer comprises first portions and second portions, each first portion is between the corresponding LED light emitting chip and the first plastic layer, and each second portion is between two adjacent LED light emitting chips, and
the first portion and the second portion corresponding to each other are in contact with each other;
wherein the adhesive layer is conformal to a structure formed by assembling a surface of the base substrate close to the encapsulation film element and the LED light emitting chips; and
wherein a surface of the plastic film close to the base substrate is parallel to the base substrate.

28-36. (canceled)

37. A display substrate, comprising a base substrate, and LED light emitting chips and an encapsulation film element on the base substrate, wherein the LED light emitting chips are between the base substrate and the encapsulation film element; and
the encapsulation film element comprises an adhesive layer and a plastic film which are stacked together, the adhesive layer is on a side of the plastic film close to the base substrate, the plastic film comprises a transparent film, and a dark coating layer is attached to a surface of the base substrate close to the encapsulation film element.

38-40. (canceled)
